(19) United States
(12) Patent Application Publication
(10) Pub. No.: US 2023/0387826 A1
(43) Pub. Date: Nov. 30, 2023

(54) AC-VOLTAGE SENSOR CIRCUIT, INVERTER CIRCUIT, AND POWER SUPPLY CIRCUIT

(71) Applicant: SHARP KABUSHIKI KAISHA, Osaka (JP)

(72) Inventor: TAKESHI SHIOMI, Osaka (JP)

(21) Appl. No.: 18/202,637

(22) Filed: May 26, 2023

(30) Foreign Application Priority Data
May 30, 2022 (JP) 2022-087815

(51) Int. Cl. H02M 7/5387; H02M 1/08; G01R 19/165

(52) U.S. Cl. CPC H02M 7/53871; H02M 1/08; G01R 19/16547

(57) ABSTRACT

An AC-voltage sensor circuit is connected to an AC output unit of an inverter circuit. A control circuit and the inverter circuit are isolation-connected. The AC-voltage sensor circuit includes a sense-signal isolation circuit. The inverter circuit and the control circuit are isolation-connected together by the AC-voltage sensor circuit. The AC output unit includes a first line and a second line that are power supply lines. The inverter circuit includes a reference-voltage node. The AC-voltage sensor circuit is configured to output a signal indicating a voltage difference between a “voltage of the first line for the reference-voltage node” and a “voltage of the second line for the reference-voltage node”.

### CROSS-REFERENCE TO RELATED APPLICATION

The present application claims priority from Japanese Application JP2022-087815, the content of which is hereby incorporated by reference into this application.

### BACKGROUND OF THE INVENTION

### 1. Field of the Invention

The following disclosure relates to an AC-voltage sensor circuit, an inverter circuit, and a power supply circuit.

### 2. Description of the Related Art

A power supply circuit from which alternating current (AC) is output requires a sensor circuit for detecting AC voltage that is output from the power supply circuit. Japanese Unexamined Patent Application Publication No. 2018-046622 discloses one example.

### SUMMARY OF THE INVENTION

However, even using such an AC-voltage sensor circuit disclosed in Japanese Unexamined Patent Application Publication No. 2018-046622 still has room for improvement.

One aspect of the present disclosure aims to offer an AC-voltage sensor circuit, an inverter circuit, and a power supply circuit that are simpler in circuit configuration than before.

To solve the above problem, an AC-voltage sensor circuit according to one aspect of the present disclosure is an AC-voltage sensor circuit connected to an AC output unit of an inverter circuit. A control circuit and the inverter circuit are isolation-connected. The AC-voltage sensor circuit includes a sense-signal isolation circuit. The inverter circuit and the control circuit are isolation-connected together by the AC-voltage sensor circuit. The AC output unit includes a first line and a second line that are power supply lines. The inverter circuit includes a reference-voltage node. The AC-voltage sensor circuit is configured to output a signal indicating the voltage difference between the “voltage of the first line for the reference-voltage node” and the “voltage of the second line for the reference-voltage node”.

The aspect of the present disclosure can offer an AC-voltage sensor circuit, an inverter circuit, and a power supply circuit that are simpler in circuit configuration than before.

### BRIEF DESCRIPTION OF THE DRAWINGS

FIG. 1 illustrates the configuration of a power supply circuit including an AC-voltage sensor circuit according to one preferred embodiment of the present invention.

### DETAILED DESCRIPTION OF THE INVENTION

Background and Problem of AC-Voltage Sensor Circuit Used in Power Supply Circuit

Power supply circuits that have been increasingly required to be miniaturized require their sensor circuits to be simplified. In particular, the sensor circuit of an inverter circuit from which AC voltage is output tends to be complicated unfortunately. This preferred embodiment discloses one example of simplifying an AC-voltage sensor circuit.

For the sake of document simplification, an “AC-voltage sensor circuit ACS1” for instance will be also expressed merely as “ACS1”.

Main Configuration of AC-Voltage Sensor Circuit ACS1 that can Sense AC Voltage Differential

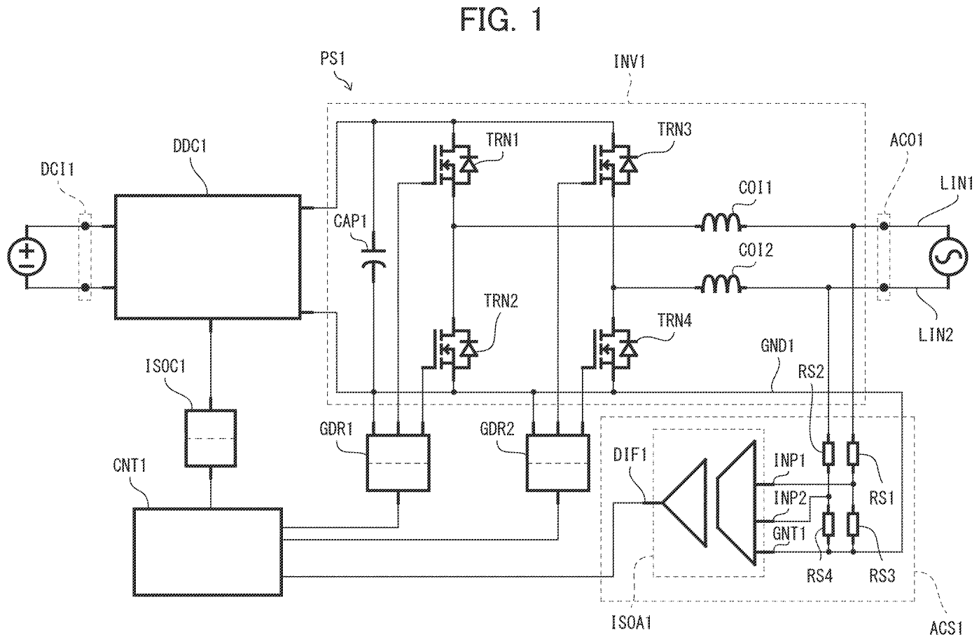

FIG. 1 illustrates the circuit configuration of a power supply circuit PS1 including the AC-voltage sensor circuit ACS1 according to one preferred embodiment of the present invention. FIG. 1 illustrates an inverter circuit INV1 connected to an AC output unit ACO1, and the AC-voltage sensor circuit ACS1 connected to ACO1. ACO1, which is drawn inside INV1 via a wire, is included in INV1 in circuit view (i.e., substantially). As illustrated in the drawing, PS1 includes ACS1, a control circuit CNT1, a DC-DC converter DDC1, a direct current (DC) input unit DCI1, a first gate driving circuit GDR1, a second gate driving circuit GDR2, and an isolated circuit ISOC1.

The control circuit CNT1 is a circuit that controls INV1. The control circuit CNT1 is isolation-connected to INV1. In more detail, INV1 and CNT1 are isolation-connected together by ACS1.

ACS1 includes a sense-signal isolation circuit in order to transmit a sense signal with isolation. Further, ACO1 includes a first line LIN1 and a second line LIN2 each of which is a power supply line. LIN1 and LIN2 are connected to INV1. INV1 includes a reference-voltage node GND1.

ACS1 is configured to output a signal indicating the voltage difference between the “voltage of LIN1 for GND1” and the “voltage of LIN2 for GND1”. The signal indicating the voltage difference is input to CNT1. CNT1 includes a microcontroller and can receive an analog signal or digital signal and can output an analog signal or digital signal. The entire power supply circuit PS1 can be thus controlled.

Isolation connection is connection that allows a signal or electric power to be transmitted though electrical connection is not established. Examples include an optical isolation circuit using a photocoupler, an isolated circuit using an electrostatic-capacitance coupling, and a transformer (transformation) circuit using magnetic coupling. These circuits can prevent leakage current, avoid an electric shock, prevent noise propagation and offer other isolation benefits.

ACS1 outputs a signal indicating the difference voltage (differential voltage) between the voltage of LIN1 and the voltage of LIN2. The signal indicating the difference voltage can be transmitted to CNT1 by the sense-signal isolation circuit of ACS1 with isolation. Types of the signal indicating the voltage difference include an analog signal and a digital signal. An example of the digital signal is a delta-sigma modulation signal.

Connection Configuration of AC-Voltage Differential Sensor Including Reference-Voltage Node GND1

As illustrated in FIG. 1, ACS1 includes a first resistor RS1, a second resistor RS2, a third resistor RS3, a fourth resistor RS4, and an isolation amplifier integrated circuit (IC) ISOA1. ISOA1 includes a first signal input terminal INP1, a second signal input terminal INP2, a reference-voltage terminal GNT1, an output terminal DIF1, and the sense-signal isolation circuit.

LIN1 is connected to INP1 via RS1, LIN2 is connected to INP2 via RS2, and GND1 is connected to GNT1. Furthermore, INP1 is connected to GND1 via RS3. INP2 is connected to GND1 via RS4. The voltage of LIN1 can be lowered by RS1 and RS3 and input to INP1. The voltage of LIN2 can be lowered by RS2 and RS4 and input to INP2.

The signal indicating the voltage difference is output from the output terminal DIF1 of ISOA1. ISOA1 adjacent to INP1 and ISOA1 adjacent to DIF1 are electrically isolated. To indicate this isolation, the circuit symbol of ISOA1 illustrated in FIG. 1 is shown separately as two blocks: right and left blocks. Such ISOA1 can detect the difference voltage between LIN1 and LIN2 with reference to GND1. In other words, ACS1 can detect the difference voltage between LIN1 and LIN2 with reference to GND1. An isolation amplifier IC having one signal input terminal uses GNT1 connected to LIN1 or LIN2, and hence, common grounding, which will be described later on, cannot be achieved.

Common Grounding of Isolated Gate Driving Circuit Through Reference-Voltage Node Connection

The first gate driving circuit GDR1 including a drive-signal isolation circuit, and the second gate driving circuit GDR2 including a drive-signal isolation circuit are connected to INV1. GDR1 and GDR2 are partly connected to GND1. To be more specific, the reference-voltage terminals of GDR1 and GDR2 adjacent to INV1 are connected to GND1. INV1 and CNT1 are isolation-connected together by the drive-signal isolation circuit of GDR1 and the drive-signal isolation circuit of GDR2.

GDR1 and GDR2 are connected to transistors, which will be described later on. GDR1 and GDR2 are ICs provided with a drive-signal isolation circuit using a photocoupler. The dotted-line symbols within the circuit diagrams of GDR1 and GDR2 in FIG. 1 indicate that the ICs are isolated inside.

In PS1, common-grounding connection is established where all the ICs, i.e., ISOA1, GDR1 and GDR2, are connected to GND1. A power supply (not shown) that is supplied to all the ICs can be a common power supply (not shown) in this case. This can simplify the sensor's circuit configuration including the commonization of a power supply (not shown). Furthermore, all the circuits connecting INV1 and CNT1 together are provided with an isolated circuit, thus establishing isolation connection between INV1 and CNT1.

Another method is connecting GNT1 of ISOA1 to LIN1 or LIN2 to detect AC voltage. The circuit configuration including ACS1 is unfortunately complicated in this case because common grounding between the ground terminals of respective GDR1 and GDR2 is difficult.

Connection Configuration Between Inverter Circuit and AC-Voltage Sensor Circuit

As illustrated in FIG. 1, INV1 includes a first coil COI1, a second coil COI2, a first transistor TRN1, a second transistor TRN2, a third transistor TRN3, a fourth transistor TRN4, and an input capacitor CAP1. The negative electrode of CAP1 is connected to GND1. The series circuit of the first transistor TRN1 and second transistor TRN2 is connected in parallel to CAP1. The connection node between TRN1 and TRN2 is connected to LIN1 via the first coil COI1. The series circuit of the third transistor TRN3 and fourth transistor TRN4 is connected in parallel to CAP1. The connection node between TRN3 and TRN4 is connected to LIN2 via the second coil COI2. This inverter circuit, although including two coils: COI1 and COI2, can include one of them.

TRN1 or TRN2 is connected to GDR1. FIG. 1 illustrates, by way of example only, a circuit configuration where TRN1 and TRN2 are both connected to GDR1. At least one of TRN1 and TRN2 needs to be connected to GDR1. CNT1 drives TRN1 or TRN2 via GDR1. REC1 or REC2 is connected to GDR2. FIG. 1 illustrates, by way of example only, a circuit configuration where REC1 and REC2 are both connected to GDR2. At least one of REC1 and REC2 needs to be connected to GDR2. CNT1 drives REC1 or REC2 via GDR2.

CNT1 can drive two transistors via GDR1. A single transistor and a single gate driving circuit may be connected on a one-to-one basis by increasing the number of gate driving circuits.

A typical inverter circuit performs a circuit operation where the voltage of LIN1 and the voltage of LIN2 do not both coincide with GND1. Hence, the differential voltage between LIN1 and LIN2 needs to be detected in order to detect AC voltage accurately. However, the commonization of a power supply (not shown) is unfortunately difficult in a conventional differential-voltage detecting circuit because it is difficult to connect the AC voltage sensor to the reference-voltage node. Using ACS1 according to the present disclosure can solve these problems.

Connection Configuration Between Inverter Circuit, DC-DC Converter, and AC-Voltage Sensor Circuit ACS1

As illustrated in FIG. 1, the power supply circuit PS1 is configured such that a DC input unit DCI1, DDC1, INV1, and ACO1 are sequentially connected from the input of its power supply toward the output of the same. DDC1, connected to INV1, is connected to CNT1 via the isolated circuit ISOC1.

INV1 is connected to DDC1 without isolation. CNT1 is isolation-connected to DDC1. DDC1 is controlled by CNT1 via the isolated circuit ISOC1. That is, the circuits connecting CNT1 to “INV1 and DDC1” are all isolated circuits. Using ACS1 in PS1 having such a circuit configuration enables a differential voltage signal to be transmitted to CNT1 with isolation. Furthermore, one CNT1 can control both INV1 and DDC1 with isolation.

It should be noted that each of the foregoing numeric values is a mere example. It is also noted that to adjust circuit operations, a resistor can be added on a wire in the circuit diagram as appropriate, or a capacitor can be added between wires in the circuit diagram as appropriate.

While there have been described what are at present considered to be certain embodiments of the invention, it will be understood that various modifications may be made thereto, and it is intended that the appended claims cover all such modifications as fall within the true spirit and scope of the invention.

What is claimed is:

1. An AC-voltage sensor circuit connected to an AC output unit of an inverter circuit,
a control circuit and the inverter circuit being isolation-connected,
the AC-voltage sensor circuit comprising a sense-signal isolation circuit,
wherein the inverter circuit and the control circuit are isolation-connected together by the AC-voltage sensor circuit,
the AC output unit includes a first line and a second line that are power supply lines,
the inverter circuit includes a reference-voltage node, and
the AC-voltage sensor circuit is configured to output a signal indicating a voltage difference between a “voltage of the first line for the reference-voltage node” and a “voltage of the second line for the reference-voltage node”.

2. The AC-voltage sensor circuit according to claim 1, comprising an isolation amplifier IC including a first signal input terminal, a second signal input terminal, a reference-voltage terminal, and the sense-signal isolation circuit,
wherein the first line is connected to the first signal input terminal via a first resistor,
the second line is connected to the second signal input terminal via a second resistor,
the reference-voltage node is connected to the reference-voltage terminal, and
the isolation amplifier IC is configured to output the signal indicating the voltage difference.

3. An inverter circuit comprising the AC-voltage sensor circuit according to claim 2,
wherein a gate driving circuit including a drive-signal isolation circuit is connected to the inverter circuit,
the gate driving circuit is partly connected to the reference-voltage node, and
the inverter circuit and the control circuit are isolation-connected together by the gate driving circuit.

4. The inverter circuit according to claim 3, comprising: an input capacitor; a first transistor; a second transistor; a third transistor; and a fourth transistor,
wherein a negative electrode of the input capacitor is connected to the reference-voltage node,
a series circuit of the first transistor and the second transistor is connected in parallel to the input capacitor,
a connection node between the first transistor and the second transistor is connected to the first line via a coil,
a series circuit of the third transistor and the fourth transistor is connected in parallel to the input capacitor,
a connection node between the third transistor and the fourth transistor is connected to the second line,
the first transistor or the second transistor is connected to the gate driving circuit, and
the control circuit is configured to drive the first transistor or the second transistor via the gate driving circuit.

5. A power supply circuit comprising the inverter circuit according to claim 4,
wherein a DC input unit, a DC-DC converter circuit, the inverter circuit, and the AC output unit are connected sequentially from an input of a power supply of the power supply circuit toward an output of the power supply of the power supply circuit, and
the DC-DC converter circuit is connected to the control circuit via an isolated circuit.
